(19) United States
(12) Patent Application Publication
(10) Pub. No.: US 2026/0068561 A1
(43) Pub. Date: Mar. 5, 2026

(54) METHOD FOR MANUFACTURING SEMICONDUCTOR DEVICE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Akiyo KAWAKAMI, Nomi Ishikawa (JP); Ryohei GEJO, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/013,065

(22) Filed: Jan. 8, 2025

(30) Foreign Application Priority Data
Sep. 5, 2024 (JP) 2024-153418

(51) Int. Cl. H01L 21/225; H10D 12/00; H10D 12/01; H10D 62/60

(52) U.S. Cl. CPC H01L 21/2253; H10D 12/038; H10D 12/481; H10D 62/60

(57) ABSTRACT

A method for manufacturing a semiconductor device according to an embodiment includes preparing a semiconductor layer including a first main surface and a second main surface and including a first semiconductor region of a first conductivity type, a second semiconductor region of a second conductivity type, a control electrode provided so as to face the second semiconductor region, and a third semiconductor region of the first conductivity type, ion-implanting an impurity of the second conductivity type into the first main surface to form a fourth semiconductor region in which an impurity concentration of the second conductivity type is a first concentration, and ion-implanting an impurity of the first conductivity type into the first main surface in an outer peripheral region of the semiconductor layer to form a fifth semiconductor region in which a net impurity concentration of the second conductivity type is a second concentration lower than the first concentration.

### CROSS-REFERENCE TO RELATED APPLICATIONS

This application is based upon and claims the benefit of priority from the prior Japanese Patent Application No. 2024-153418, filed on Sep. 5, 2024; the entire contents of which are incorporated herein by reference.

### FIELD

Embodiments described herein relate generally to a method for manufacturing a semiconductor device and a semiconductor device.

### BACKGROUND

In a semiconductor device such as an insulated gate bipolar transistor (IGBT), it is desirable that avalanche capability is high.

### BRIEF DESCRIPTION OF THE DRAWINGS

FIG. 1 is a plan view of a semiconductor device according to a first embodiment;

FIG. 2 is a bottom view of the semiconductor device according to the first embodiment;

FIG. 3 is a cross-sectional view of the semiconductor device according to the first embodiment, taken along line A-A in FIGS. 1 and 2;

FIG. 4A is a cross-sectional view for describing an example of a manufacturing process of the semiconductor device according to the first embodiment;

FIG. 4B is a cross-sectional view for describing an example of the manufacturing process of the semiconductor device according to the first embodiment, following FIG. 4A;

FIG. 4C is a cross-sectional view for describing an example of the manufacturing process of the semiconductor device according to the first embodiment, following FIG. 4B;

FIG. 4D is a cross-sectional view for describing an example of the manufacturing process of the semiconductor device according to the first embodiment, following FIG. 4C;

FIG. 4E is a cross-sectional view for describing an example of the manufacturing process of the semiconductor device according to the first embodiment, following FIG. 4D;

FIG. 4F is a cross-sectional view for describing an example of the manufacturing process of the semiconductor device according to the first embodiment, following FIG. 4E;

FIG. 5 is a plan view of a semiconductor device according to a second embodiment;

FIG. 6 is a bottom view of the semiconductor device according to the second embodiment;

FIG. 7 is a cross-sectional view of the semiconductor device according to the second embodiment, taken along line B-B in FIGS. 5 and 6;

FIG. 8 is a bottom view of a semiconductor device according to a first modification of the second embodiment;

FIG. 9 is a graph illustrating evaluation results of a short circuit tolerance in the semiconductor devices according to the first embodiment, the second embodiment, and a comparative example;

FIG. 10A is a cross-sectional view for describing an example of the manufacturing process of the semiconductor device according to the second embodiment;

FIG. 10B is a cross-sectional view for describing an example of the manufacturing process of the semiconductor device according to the second embodiment, following FIG. 10A;

FIG. 10C is a cross-sectional view for describing an example of the manufacturing process of the semiconductor device according to the second embodiment, following FIG. 10B;

FIG. 11 is a bottom view of a semiconductor device according to a second modification of the second embodiment; and

FIG. 12 is a bottom view of a semiconductor device according to a third modification of the second embodiment.

### DETAILED DESCRIPTION

A method for manufacturing a semiconductor device according to an embodiment includes preparing a semiconductor layer including a first main surface and a second main surface and including a first semiconductor region of a first conductivity type, a second semiconductor region of a second conductivity type located on the first semiconductor region, a control electrode provided so as to face the second semiconductor region with an insulating region interposed therebetween, and a third semiconductor region of the first conductivity type located between the second main surface and the second semiconductor region, ion-implanting an impurity of the second conductivity type into the first main surface of the semiconductor layer to form a fourth semiconductor region in which an impurity concentration of the second conductivity type is a first concentration, and ion-implanting an impurity of the first conductivity type into the first main surface of the semiconductor layer in an outer peripheral region extending from a side portion of the semiconductor layer to an inside of the semiconductor layer to form a fifth semiconductor region in which a net impurity concentration of the second conductivity type after the impurity of the first conductivity type and the impurity of the second conductivity type compensate each other is a second concentration lower than the first concentration.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

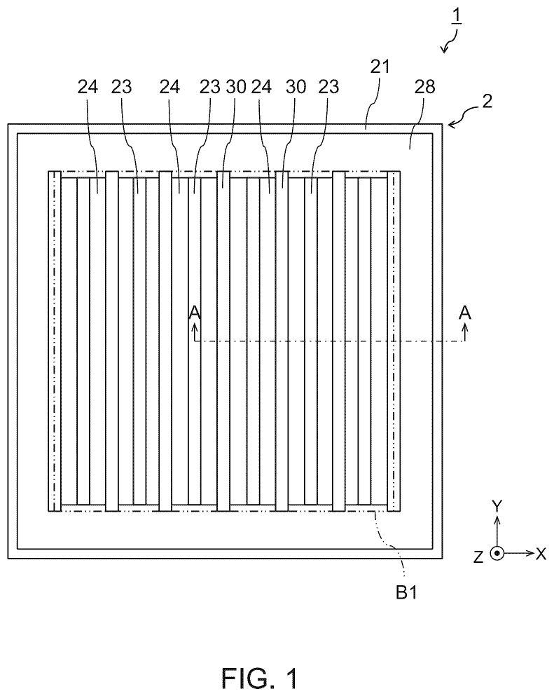

Further, for convenience of description, an XYZ orthogonal coordinate system is employed as illustrated in FIGS. 1 to 3 or the like. A Z-axis direction is a stacking direction (thickness direction) of the semiconductor devices. Further, in the Z-axis direction, the emitter electrode side is also referred to as “upper”, and the collector electrode side is also referred to as “lower”. However, this expression is for convenience and independent of the direction of gravity.

Further, in the following description, notations of n⁺, n, n⁻, and p⁺, p, and p⁻may be used to represent a relative level of impurity concentration in each conductivity type. That is, n⁺ indicates that it has a relatively higher effective n-type impurity concentration than n, and n⁻ indicates that it has a relatively lower effective n-type impurity concentration than n. Further, p⁺ indicates that it has a relatively higher effective p-type impurity concentration than p, and p⁻ indicates that it has a relatively lower effective p-type impurity concentration than p. Note that, in the present application, the expression “effective p-type (n-type) impurity concentration” means a net p-type (n-type) impurity concentration after p-type impurity and n-type impurity compensate each other when both the p-type impurity and the n-type impurity are contained in each region. On the other hand, in the present application, the simple expression “p-type (n-type) impurity concentration” means the p-type (n-type) impurity concentration before these impurities compensate each other even when both the p-type impurity and the n-type impurity are contained in each region. The n-type, n⁺-type, and n⁻-type are examples of a first conductivity type in the claims. The p-type, p⁺-type, and p⁻-type are examples of a second conductivity type in the claims. Note that, in the following description, the n-type and the p-type may be reversed. That is, the first conductivity type may be p-type.

Further, the impurity concentration of the semiconductor region can be measured by, for example, secondary ion mass spectrometry (SIMS). Further, the relative level of the impurity concentration can also be determined from the level of the carrier concentration obtained by, for example, scanning capacitance microscopy (SCM).

Further, dimensions such as a width of the semiconductor region can be measured by, for example, analysis of a surface and a cross section by a transmission electron microscope (TEM), an energy dispersive X-ray spectroscopy (EDX), or a scanning electron microscope (SEM).

### First Embodiment

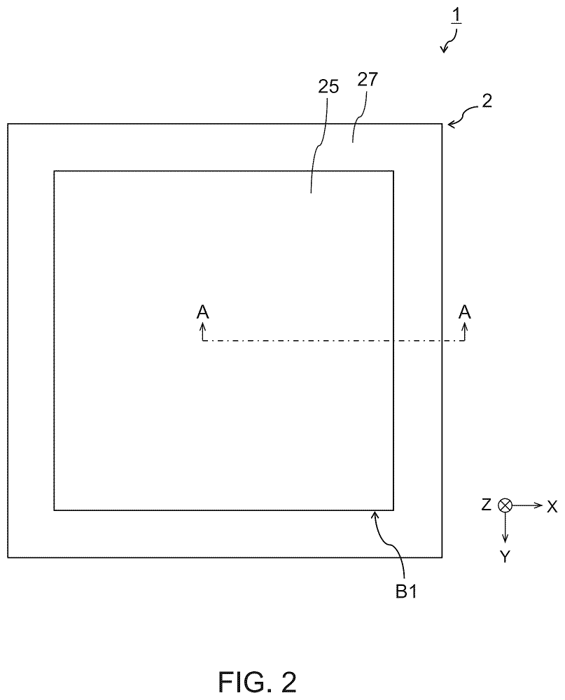

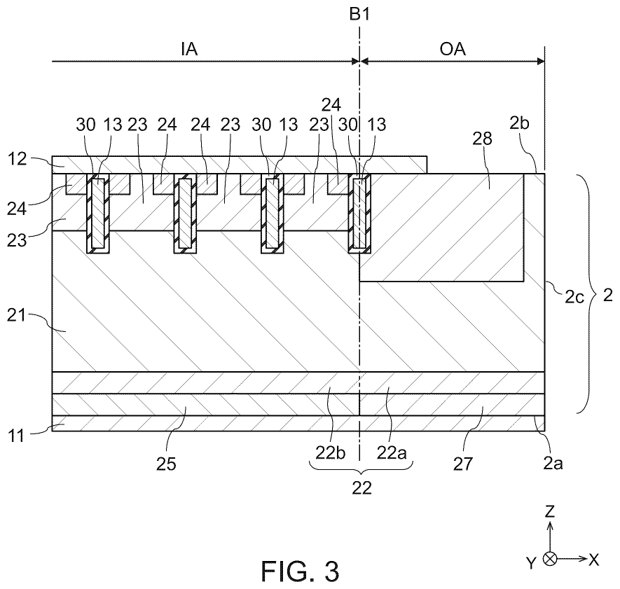

A semiconductor device 1 according to a first embodiment will be described with reference to FIGS. 1 to 3. FIG. 1 is a plan view of a semiconductor device 1 according to the first embodiment. FIG. 2 is a bottom view of the semiconductor device 1 according to the first embodiment. FIG. 3 is a cross-sectional view of the semiconductor device 1 according to the first embodiment, taken along line A-A in FIGS. 1 and 2. Note that, in FIG. 1, an emitter electrode 12 is omitted, and in FIG. 2, a collector electrode 11 is omitted.

The semiconductor device 1 is, for example, an IGBT. In the present embodiment, a case where the semiconductor device 1 is a vertical IGBT having a trench gate structure will be described as an example. Note that the semiconductor device 1 may be a vertical IGBT having a planar gate structure, or the like.

As illustrated in FIG. 3, the semiconductor device 1 according to the present embodiment includes a semiconductor layer 2, a collector electrode 11, an emitter electrode 12, a gate electrode 13, and an insulating region 30.

The semiconductor layer 2 includes a lower surface 2a, an upper surface 2b opposite to the lower surface 2a, and a side portion 2c. The lower surface 2a and the upper surface 2b are examples of a first main surface and a second main surface in the claims, respectively.

Further, the semiconductor layer 2 has an outer peripheral region OA extending from the side portion 2c of the semiconductor layer 2 to an inside of the semiconductor layer 2 and an inner region IA inside the outer peripheral region OA. The inner region IA is a region serving as a main path of a current during operation of the semiconductor device 1, and is also referred to as a cell region. In FIGS. 1 to 3, reference numeral B1 represents a boundary between the outer peripheral region OA and the inner region IA. As illustrated in FIGS. 1 and 2, the outer peripheral region OA located outside the boundary B1 surrounds the inner region IA located inside the boundary B1.

As illustrated in FIG. 3, for example, an n base region 21, a buffer region 22, a p base region 23, an emitter region 24, a collector region 25, a low-concentration region 27, and a guard ring region 28 are provided in the semiconductor layer 2. Details of these regions will be described later.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as an n-type impurity, and for example, boron (B) is used as a p-type impurity.

The collector electrode 11 functions as a collector electrode of the IGBT. The collector electrode 11 is provided on the lower surface 2a of the semiconductor layer 2 and is in contact with the collector region 25 and the low-concentration region 27. The collector electrode 11 is an example of a first electrode in the claims. The collector electrode 11 is formed by, for example, a material containing at least one of aluminum (Al), copper (Cu), titanium (Ti), tungsten (W), or the like.

The emitter electrode 12 functions as an emitter electrode of the IGBT. The emitter electrode 12 is provided on the upper surface 2b of the semiconductor layer 2 and is in contact with the p base region 23, the emitter region 24, and a guard region. The emitter electrode 12 is an example of a second electrode in the claims. The emitter electrode 12 is formed by, for example, a material containing at least one of aluminum (Al), copper (Cu), titanium (Ti), tungsten (W), or the like.

The gate electrode 13 functions as a gate electrode of the IGBT. The gate electrode 13 is provided so as to face the p base region 23 with the insulating region 30 interposed therebetween. In the present embodiment, the gate electrode 13 is provided in the p base region 23 with the insulating region 30 interposed therebetween, and is electrically insulated from the emitter electrode 12 and the semiconductor layer 2 by the insulating region 30. The gate electrode 13 is an example of a control electrode in the claims. The gate electrode 13 is formed by, for example, polysilicon containing p-type or n-type impurities, or the like. When a voltage is applied to the gate electrode 13, a channel is formed in the p base region 23, and carriers flow between the n base region 21 and the emitter region 24. Thus, the IGBT is turned on.

The insulating region 30 is provided so as to cover the upper surface of the gate electrode 13 and sidewalls of a plurality of trenches provided on the upper surface 2b of the semiconductor layer 2. The insulating region 30 is an insulating film containing, for example, silicon oxide or silicon nitride.

Next, details of each region provided in the semiconductor layer 2 will be described.

As illustrated in FIG. 3, the n base region 21 functions as an n base region (drift region) of the IGBT. The n base region 21 is located above the buffer region 22 (above the collector electrode 11). The n base region 21 is an example of a first semiconductor region in the claims. The n base region 21 is, for example, an n⁻-type semiconductor region. An effective n-type impurity concentration of the n base region 21 is, for example, equal to or more than 1×10¹² cm⁻³ and equal to or less than 1×10¹⁵ cm⁻³.

The buffer region 22 functions as a buffer region of the IGBT. The buffer region 22 is located between the n base region 21 and the collector region 25. The buffer region 22 is an example of a sixth semiconductor region in the claims. The buffer region 22 is, for example, an n⁺-type semiconductor region. That is, the n-type impurity concentration of the buffer region 22 is higher than the n-type impurity concentration of the n base region 21. Further, an effective n-type impurity concentration of the buffer region 22 is higher than the effective n-type impurity concentration of the n base region 21. The effective n-type impurity concentration of the buffer region 22 is, for example, equal to or more than 1×10¹⁵ cm⁻³ and equal to or less than 1×10¹⁷ cm⁻³.

As illustrated in FIG. 3, the buffer region 22 includes a first portion 22a located in the outer peripheral region OA and a second portion 22b located in the inner region IA. The first portion 22a is located on the low-concentration region 27, and the second portion 22b is located on the collector region 25.

In the present embodiment, an n-type impurity concentration in the first portion 22a is equal to an n-type impurity concentration in the second portion 22b. That is, an effective n-type impurity concentration in the first portion 22a is equal to an effective n-type impurity concentration in the second portion 22b. Note that the n-type impurity concentration in the first portion 22a may be higher than the n-type impurity concentration in the second portion 22b. In this case, the effective n-type impurity concentration in the first portion 22a is higher than the effective n-type impurity concentration in the second portion 22b.

Note that the buffer region 22 need not be provided. In this case, for example, the n base region 21 is also provided at the position of the buffer region 22. Alternatively, the n base region 21 need not be provided. In this case, for example, the buffer region 22 is also provided at the position of the n base region 21. Further, in this case, the buffer region 22 is an example of a first semiconductor region in the claims.

The p base region 23 functions as a p base region of the IGBT. The p base region 23 is located above the n base region 21. The p base region 23 is an example of a second semiconductor region in the claims. The p base region 23 is, for example, a p-type semiconductor region. An effective p-type impurity concentration of the p base region 23 is, for example, equal to or more than 1×10¹⁷ cm⁻³ and equal to or less than 1×10¹⁹ cm⁻³. As illustrated in FIG. 1, the p base region 23 extends in the Y-axis direction. Further, in the example of FIG. 3, the p base region 23 has a third portion located below the emitter region 24 and a fourth portion extending from the third portion toward the upper surface 2b of the semiconductor layer 2 and penetrating the emitter region 24. The fourth portion is in contact with the emitter electrode 12 and is electrically connected to the emitter electrode 12. Note that an effective p-type impurity concentration of the fourth portion may be higher than an effective p-type impurity concentration of the third portion.

The emitter region 24 functions as an emitter region of the IGBT. The emitter region 24 is located above the p base region 23. The emitter region 24 is in contact with the emitter electrode 12 and is electrically connected to the emitter electrode 12. The emitter region 24 is an example of a third semiconductor region in the claims. As illustrated in FIG. 1, the emitter region 24 extends in a Y-axis direction. The emitter region 24 is, for example, an n⁺-type semiconductor region. An effective n-type impurity concentration of the emitter region 24 is, for example, equal to or more than 1×10¹⁸ cm⁻³ and equal to or less than 1×10²¹ cm⁻³.

The collector region 25 functions as a collector region of the IGBT. As illustrated in FIG. 3, the collector region 25 is located between the collector electrode 11 and the n base region 21, more particularly, between the collector electrode 11 and the buffer region 22. The collector region 25 is in contact with the collector electrode 11 and is electrically connected to the collector electrode 11. The collector region 25 is an example of a fourth semiconductor region in the claims. The collector region 25 is, for example, a p-type semiconductor region. A p-type impurity concentration of the collector region 25 is a first concentration. Further, an effective p-type impurity concentration of the collector region 25 is, for example, about 5×10¹⁷ cm⁻³.

The low-concentration region 27 is provided in the outer peripheral region OA of the semiconductor layer 2. As illustrated in FIG. 2, the low-concentration region 27 is provided so as to surround the collector region 25. As illustrated in FIG. 3, the low-concentration region 27 is in contact with the collector electrode 11 and is electrically connected to the collector electrode 11. The low-concentration region 27 is an example of a fifth semiconductor region in the claims. The low-concentration region 27 contains n-type impurities and p-type impurities. A p-type impurity concentration of the low-concentration region 27 is, for example, the first concentration that is the same as the p-type impurity concentration of the collector region 25. On the other hand, the low-concentration region 27 is, for example, a p⁻-type semiconductor region. That is, an effective p-type impurity concentration of the low-concentration region 27 is a second concentration lower than the first concentration. The second concentration is, for example, about 1×10¹⁷ cm⁻³.

Note that the values of the first concentration and the second concentration described above are examples, and may change by about 1 to 2 digits in other embodiments.

Further, as will be described later, the collector region 25 and the low-concentration region 27 are formed by forming a p-type semiconductor region (p region 250) on the lower surface 2a of the semiconductor layer 2 and then counter-doping the lower surface 2a of the semiconductor layer 2 in the outer peripheral region OA with n-type impurities. Therefore, an n-type impurity concentration of the low-concentration region 27 is higher than an n-type impurity concentration of the collector region 25.

In the present embodiment, as illustrated in FIGS. 1 and 3, the guard ring region 28 is provided. The guard ring region 28 is provided in the outer peripheral region OA of the semiconductor layer 2. The guard ring region 28 is in contact with the emitter electrode 12 and is electrically connected to the emitter electrode 12. Further, as illustrated in FIG. 1, the guard ring region 28 is in contact with an end of the p base region 23 in the Y-axis direction. The guard ring region 28 is, for example, a p-type semiconductor region. The effective p-type impurity concentration of the guard ring region 28 is, for example, equal to or more than 1×10¹⁷ cm⁻³ and equal to or less than 1×10¹⁹ cm⁻³. By providing the guard ring region 28, the withstand voltage of the semiconductor device 1 can be improved.

In the example of FIG. 3, both the low-concentration region 27 and the guard ring region 28 are provided in the outer peripheral region OA. On the other hand, neither the low-concentration region 27 nor the guard ring region 28 is provided in the inner region IA. In other words, the inner ends of the low-concentration region 27 and the guard ring region 28 coincide with each other, and both are located on the boundary B1. Note that the inner ends of the low-concentration region 27 and the guard ring region 28 need not coincide with each other. That is, the inner end of the low-concentration region 27 may be located inside or outside the inner end of guard ring region 28.

Note that, although not illustrated, the semiconductor device 1 may further include a field plate electrode (FP electrode) provided in the semiconductor layer 2 with an insulating region interposed therebetween. The FP electrode is electrically insulated from the semiconductor layer 2 by the insulating region, and is electrically connected to the emitter electrode 12. By providing such an FP electrode, when the IGBT is in the off state, a depletion layer extends from the FP electrode to the n base region 21 around the FP electrode by the voltage applied between the collector electrode 11 and the emitter electrode 12. By connecting this depletion layer to the depletion layer of the adjacent FP electrode, it is possible to improve the withstand voltage of the semiconductor device 1.

Further, the configuration of the semiconductor device 1 illustrated in FIGS. 1 to 3 is an example, and the present embodiment is not limited thereto. For example, the number of gate electrodes 13 extending in the Y-axis direction, that is, the number of insulating regions 30 may be larger or smaller than that in the example of FIG. 1. Furthermore, a gate pad may be provided on the upper surface 2b of the semiconductor layer 2.

As described above, the semiconductor device 1 according to the first embodiment includes the semiconductor layer 2, the collector electrode 11, the emitter electrode 12, the n base region 21 of the first conductivity type, the p base region 23 of the second conductivity type, the gate electrode 13, the emitter region 24 of the first conductivity type, the collector region 25 of the second conductivity type, and the low-concentration region 27 of the second conductivity type. The semiconductor layer 2 includes the lower surface 2a and the upper surface 2b. The collector electrode 11 is provided on the lower surface 2a of the semiconductor layer 2. The emitter electrode 12 is provided on the upper surface 2b of the semiconductor layer 2. The n base region 21 is provided in the semiconductor layer 2. The p base region 23 is provided in the semiconductor layer 2 and is located on the n base region 21. The gate electrode 13 is provided so as to face the p base region 23 with the insulating region 30 interposed therebetween. The emitter region 24 is provided in the semiconductor layer 2, is located on the p base region 23, and is electrically connected to the emitter electrode 12. The collector region 25 is provided in the semiconductor layer 2, is located between the collector electrode 11 and the n base region 21, is electrically connected to the collector electrode 11, and has a p-type impurity concentration of the first concentration. The low-concentration region 27 is provided in the outer peripheral region OA extending from the side portion 2c of the semiconductor layer 2 to the inside of the semiconductor layer 2, and is electrically connected to the collector electrode 11. In the low-concentration region 27, n-type impurities and p-type impurities are included, the p-type impurity concentration is the first concentration, and a net p-type impurity concentration after the n-type impurities and the p-type impurities compensate each other is the second concentration lower than the first concentration.

In the present embodiment, the avalanche capability of the semiconductor device 1 can be improved by providing the low-concentration region 27.

### Method of Manufacturing Semiconductor Device 1

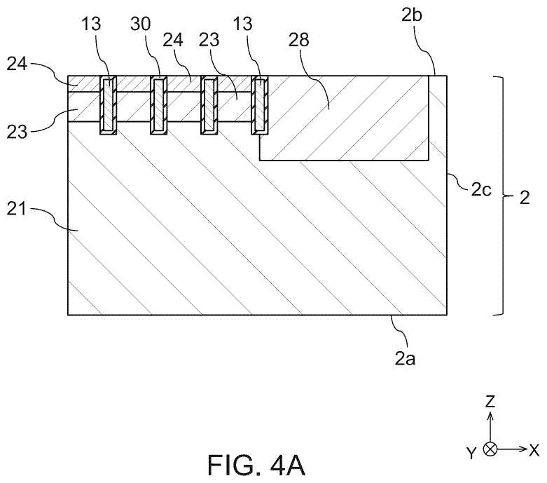

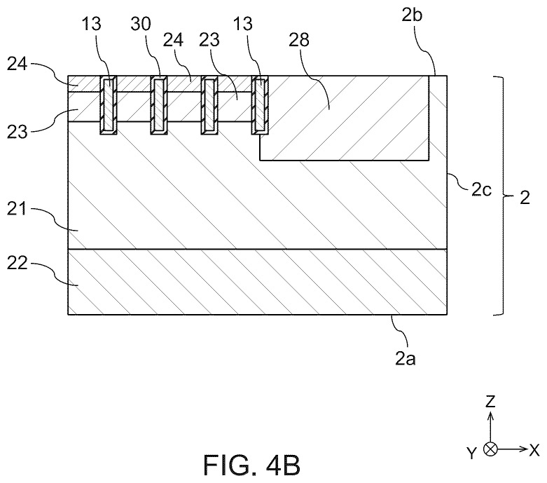

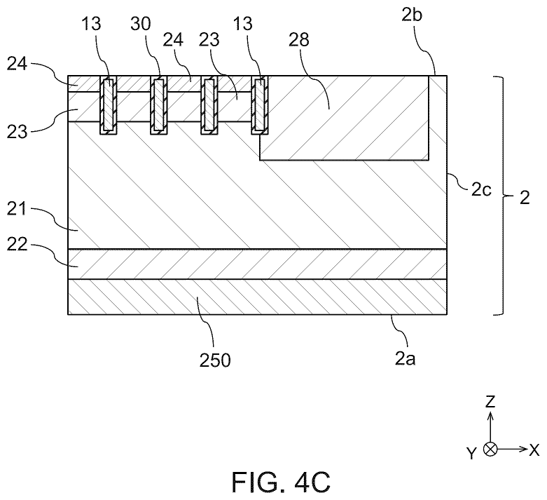

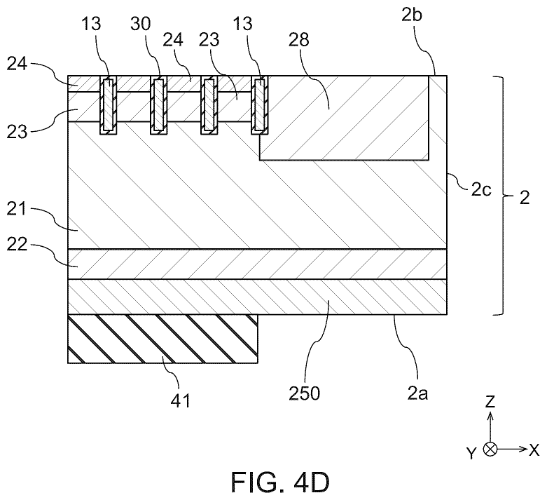

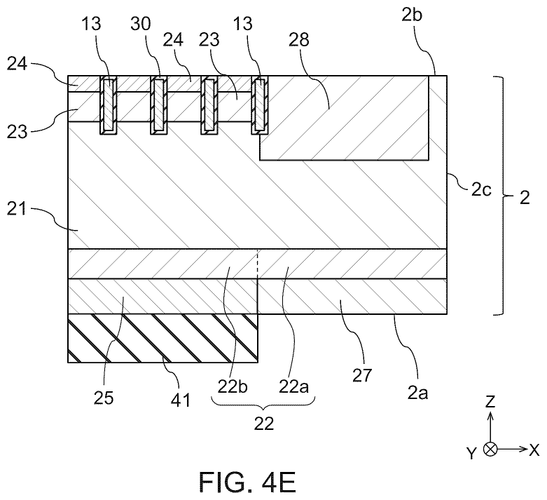

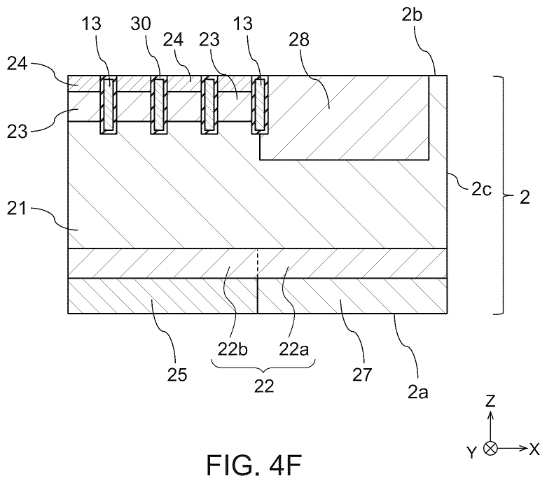

Next, an example of a method for manufacturing the semiconductor device 1 according to the present embodiment will be described with reference to FIGS. 4A to 4F. FIGS. 4A to 4F are cross-sectional views for describing an example of a manufacturing process of the semiconductor device 1 according to the first embodiment. Note that, in FIGS. 4A to 4F, a portion (fourth portion) penetrating the emitter region 24 in the p base region 23 is omitted.

First, as illustrated in FIG. 4A, the semiconductor layer 2 including the lower surface 2a and the upper surface 2b opposite to the lower surface 2a is prepared. The semiconductor layer 2 includes the gate electrode 13, the n base region 21, the p base region 23, the emitter region 24, the guard ring region 28, and the insulating region 30.

Next, as illustrated in FIG. 4B, by ion-implanting n-type impurities into the lower surface 2a of the semiconductor layer 2, the buffer region 22 is formed under the n base region 21. The n-type impurity used at this time is, for example, at least one of phosphorus (P) or arsenic (As). The n-type impurity concentration of the buffer region 22 is higher than the n-type impurity concentration of the n base region 21.

Next, as illustrated in FIG. 4C, p-type impurities are ion-implanted into the lower surface 2a of the semiconductor layer 2 to form the p region 250. The p-type impurity used at this time is, for example, boron (B). The p region 250 is an example of a fourth semiconductor region in the claims. The p region 250 is, for example, a p-type semiconductor region. Further, the p-type impurity concentration in the formed p region 250 is the first concentration.

Next, as illustrated in FIG. 4D, a resist 41 is formed on a part of the lower surface 2a of the semiconductor layer 2. More specifically, a resist is formed on the entire lower surface 2a of the semiconductor layer 2, and then a portion of the resist located in the outer peripheral region OA is removed by photolithography or the like. Thus, the resist 41 is formed on the lower surface 2a of the semiconductor layer 2 other than the outer peripheral region OA, that is, in the inner region IA.

Next, as illustrated in FIG. 4E, n-type impurities are ion-implanted (counter-doped) into the lower surface 2a of the semiconductor layer 2 to form the low-concentration region 27. More specifically, in the lower surface 2a of the semiconductor layer 2, the low-concentration region 27 is formed by ion-implanting n-type impurities into the outer peripheral region OA not covered with the resist 41. The n-type impurity used at this time is, for example, at least one of phosphorus (P) or arsenic (As). The p-type impurity concentration of the low-concentration region 27 is the first concentration. On the other hand, the effective p-type impurity concentration of the low-concentration region 27 is the second concentration lower than the first concentration. Through this step, the collector region 25 is formed in a portion of the p region 250 covered with the resist 41. Note that the n-type impurity concentration of the low-concentration region 27 is higher than the n-type impurity concentration of the collector region 25.

Note that, in the step of forming the low-concentration region 27, some n-type impurities may diffuse into the buffer region 22. Accordingly, when the buffer region 22 is divided into the first portion 22a located in the outer peripheral region OA and the second portion 22b located in the inner region IA, the n-type impurity concentration in the first portion 22a may be higher than the n-type impurity concentration in the second portion 22b.

Next, as illustrated in FIG. 4f, the resist 41 is removed.

Thereafter, although not illustrated, the collector electrode 11 and the emitter electrode 12 are formed on the lower surface 2a and the upper surface 2b of the semiconductor layer 2, respectively.

Through the above steps, the semiconductor device 1 is manufactured.

As described above, in the method for manufacturing the semiconductor device 1 according to the first embodiment, the semiconductor layer 2 including the lower surface 2a and the upper surface 2b and including the n base region 21 of the first conductivity type, the p base region 23 of the second conductivity type located on the n base region 21, the gate electrode 13 provided so as to face the p base region 23 with the insulating region 30 interposed therebetween, and the emitter region 24 of the first conductivity type located between the upper surface 2b of the semiconductor layer 2 and the p base region 23 is prepared, a p-type impurity is ion-implanted into the lower surface 2a of the semiconductor layer 2 to form the p region 250 having the first concentration of p-type impurities, an n-type impurity is ion-implanted into the lower surface 2a of the semiconductor layer 2 in the outer peripheral region OA of the semiconductor layer 2, and the low-concentration region 27 is formed in which the net p-type impurity concentration after the n-type impurity and the p-type impurity compensate each other is the second concentration lower than the first concentration.

According to the method for manufacturing the semiconductor device 1 according to the present embodiment, the low-concentration region 27 having a lower effective p-type impurity concentration than the collector region 25 can be formed in the outer peripheral region OA. Accordingly, the semiconductor device 1 with improved avalanche capability can be manufactured.

Further, in the method for manufacturing the present embodiment, after the p region 250 is formed, the low-concentration region 27 is formed by ion-implanting n-type impurities into the outer peripheral region OA (counter-doping). Furthermore, forming the low-concentration region 27 includes, after forming a resist on the lower surface 2a of the semiconductor layer 2, removing a portion of the resist located in the outer peripheral region OA, ion-implanting n-type impurities into the lower surface 2a of the semiconductor layer 2, and removing a remaining portion (the resist 41) of the resist. Thus, it is possible to avoid performing photolithography or the like in the inner region IA, and it is possible to avoid occurrence of a region (pattern defect) having a lower effective p-type impurity concentration than the collector region 25 at an unintended position of the collector region 25 due to adhesion of dust, remaining of resist, or the like in the inner region IA. As a result, it is possible to suppress a decrease in short circuit tolerance of the semiconductor device 1 accompanied by pattern defects in the collector region 25.

Note that, by intentionally forming a region having a low effective p-type impurity concentration in the collector region 25, it is possible to increase the switching speed of the semiconductor device 1 while suppressing a decrease in short circuit tolerance. Hereinafter, such a case will be described as a second embodiment.

### Second Embodiment

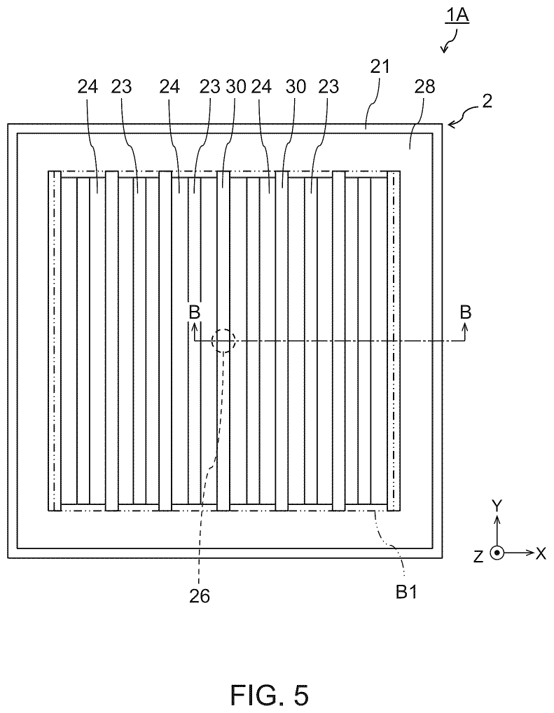

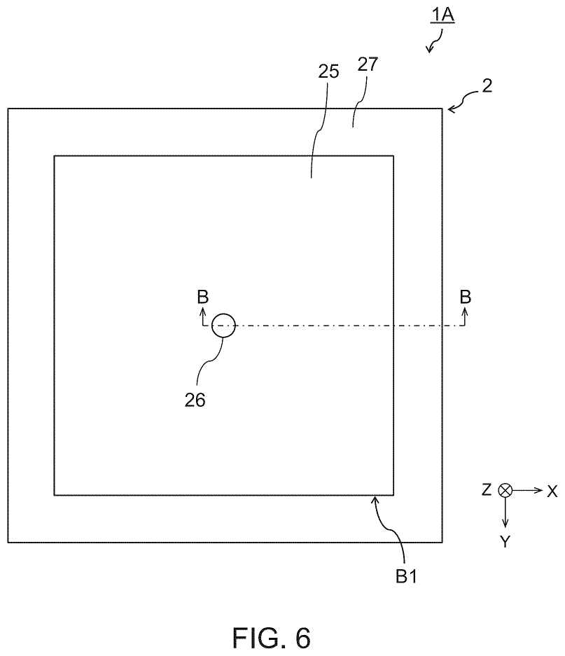

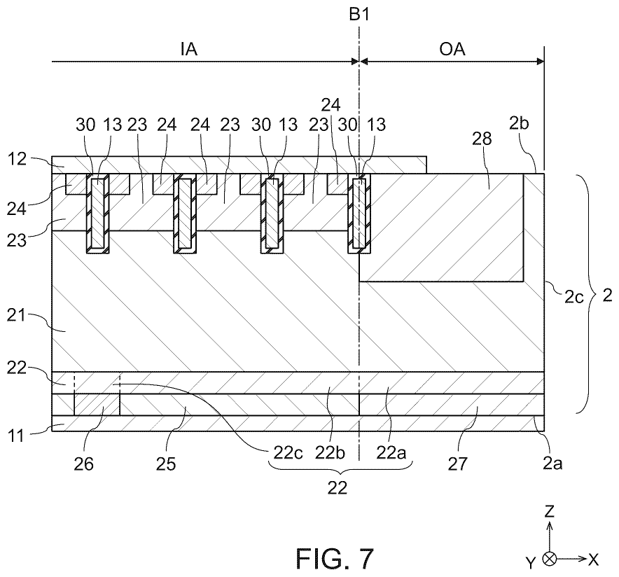

A semiconductor device 1A according to the second embodiment will be described with reference to FIGS. 5 to 7. FIG. 5 is a plan view of the semiconductor device 1A according to the second embodiment. FIG. 6 is a bottom view of the semiconductor device 1A according to the second embodiment. FIG. 7 is a cross-sectional view of the semiconductor device 1A according to the second embodiment, taken along line B-B in FIGS. 5 and 6. Note that, in FIG. 5, the emitter electrode 12 is omitted, and in FIG. 6, the collector electrode 11 is omitted. One of the differences between the present embodiment and the first embodiment is the presence of a low-concentration region 26. Hereinafter, the present embodiment will be described focusing on differences from the first embodiment.

As illustrated in FIGS. 5 to 7, the semiconductor device 1A further includes a low-concentration region 26. The low-concentration region 26 is provided so as to be surrounded by the collector region 25 in the semiconductor layer 2. That is, the collector region 25 is provided on both sides of the low-concentration region 26 along an X-axis direction, and the collector region 25 is provided on both sides of the low-concentration region 26 along the Y-axis direction. Further, the low-concentration region 26 is separated from the low-concentration region 27 by the collector region 25. The low-concentration region 26 is in contact with the collector electrode 11 and is electrically connected to the collector electrode 11. The low-concentration region 26 is an example of a seventh semiconductor region in the claims. The low-concentration region 27 contains n-type impurities and p-type impurities. A p-type impurity concentration of the low-concentration region 27 is, for example, the first concentration that is the same as the p-type impurity concentration of the collector region 25. On the other hand, the low-concentration region 26 is, for example, a p³¹ -type semiconductor region. That is, an effective p-type impurity concentration of the low-concentration region 26 is a third concentration lower than the first concentration. The third concentration is, for example, equal to or more than 1×10¹⁶ cm⁻³ and less than 5×10¹⁷ cm⁻³.

Note that, as described later, the low-concentration region 26 is formed by counter-doping a p region 250 with an n-type impurity. Therefore, an n-type impurity concentration of the low-concentration region 26 is higher than an n-type impurity concentration of the collector region 25.

As illustrated in FIG. 7, in the present embodiment, the buffer region 22 includes a first portion 22a located in the outer peripheral region OA, and a second portion 22b and a fifth portion 22c located in the inner region IA. The first portion 22a is located on the low-concentration region 27, the second portion 22b is located on the collector region 25, and the fifth portion 22c is located on the low-concentration region 26.

In the present embodiment, an n-type impurity concentration in the fifth portion 22c is equal to an n-type impurity concentration in the second portion 22b. That is, an effective n-type impurity concentration in the fifth portion 22c is equal to an effective n-type impurity concentration in the second portion 22b. Note that the n-type impurity concentration in the fifth portion 22c may be higher than the n-type impurity concentration in the second portion 22b. In this case, the effective n-type impurity concentration in the fifth portion 22c is higher than the effective n-type impurity concentration in the second portion 22b.

As illustrated in FIGS. 5 and 6, in the present embodiment, the low-concentration region 26 is located at the center of the inner region IA, that is, at the center of the collector region 25.

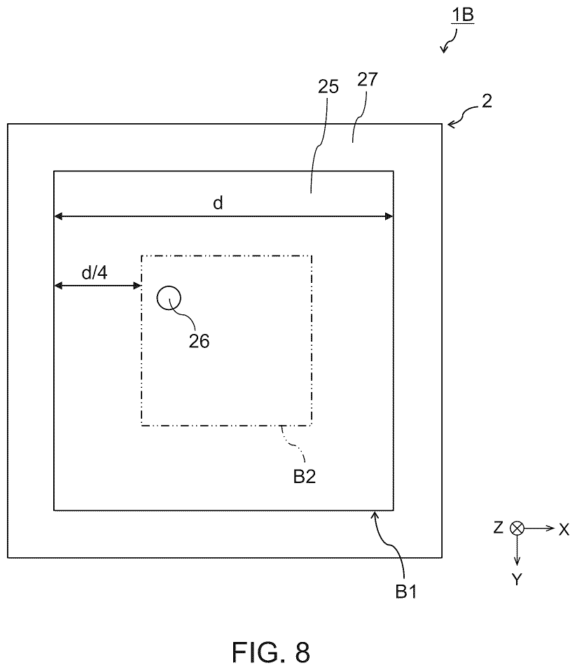

Note that the low-concentration region 26 may be located at a position other than the center of the inner region IA. FIG. 8 is a bottom view of a semiconductor device 1B according to a first modification of the second embodiment. In FIG. 8, reference numeral B2 denotes a position separated from the boundary B1 between the outer peripheral region OA and the inner region IA by ¼ of a width d of the inner region IA. In the example of FIG. 8, the low-concentration region 26 is not located at the center of the inner region IA. However, the low-concentration region 26 is located in a region (hereinafter, also referred to as a “cell center”) inside boundary B2, and is not provided in a region (hereinafter, also referred to as a “cell end”) between the boundary B1 and boundary B2. In other words, the low-concentration region 26 is separated from the boundary B1 by ¼ or more of the width d of the inner region IA. More specifically, the low-concentration region 26 is separated from the boundary B1 by ¼ or more of the length in the X-axis direction of the inner region IA and is separated from the boundary B1 by ¼ or more of the length in the Y-axis direction of the inner region IA.

Further, in the example of FIG. 8, the planar shape of the inner region IA is a square. The planar shape of the inner region IA is not limited thereto and may be rectangular. Also in this case, the low-concentration region 26 is provided so as to be separated from the boundary B1 by ¼ or more of the length in the X-axis direction of the inner region IA and so as to be separated from the boundary B1 by ¼ or more of the length in the Y-axis direction of the inner region IA.

In the examples of FIGS. 6 and 8, a width of the low-concentration region 26 is equal to or more than 1/60 of a width of the semiconductor layer 2. More specifically, the lengths in the X-axis direction and the Y-axis direction of the low-concentration region 26 are equal to or more than 1/60 of the larger one of the lengths in the X-axis direction and the Y-axis direction of the semiconductor layer 2.

Further, in the examples of FIGS. 6 and 8, the planar shape of the low-concentration region 26 is circular. Note that the planar shape of the low-concentration region 26 is arbitrary, and may be a rectangle, a polygon, or the like.

By providing the collector region 25, the low-concentration region 26, and the low-concentration region 27, the effective p-type impurity concentration along the X-axis direction and the Y-axis direction increases from the low-concentration region 26 to the collector region 25, and then decreases from the collector region 25 to the low-concentration region 27.

In the present embodiment, the second concentration that is the effective p-type impurity concentration of the low-concentration region 27 is equal to the third concentration that is the effective p-type impurity concentration of the low-concentration region 26. Note that the second concentration may be lower than the third concentration.

Note that the value of the third concentration described above is an example, and may change by about 1 to 2 digits in other embodiments.

Further, the configuration of the semiconductor device 1A illustrated in FIGS. 6 to 8 is an example, and the present embodiment is not limited thereto. For example, in the examples of FIGS. 6 and 8, the low-concentration region 26 is provided below the gate electrode 13. The present invention is not limited to this, and the gate electrode 13 may be provided outside the low-concentration region 26 and below the gate electrode. That is, the positional relationship between the low-concentration region 26 and the gate electrode 13 is arbitrary.

In the present embodiment, the low-concentration region 26 is provided so as to be surrounded by the collector region 25. Thus, the hole injection amount from the collector region 25 to the n base region 21 is suppressed, and the switching loss of the semiconductor device 1A is reduced. Here, the switching loss is a power loss generated when the semiconductor device 1A is turned on and off. According to the present embodiment, since the low-concentration region 26 is surrounded by the collector region 25, the hole injection amount is more effectively suppressed than when the low-concentration region is arranged around the collector region 25. Therefore, according to the present embodiment, the switching of the semiconductor device 1A can be speeded up.

Further, in the present embodiment, the p-type impurity concentration of the low-concentration region 27 is equal to the p-type impurity concentration of the low-concentration region 26. Thus, the low-concentration region 26 and the low-concentration region 27 can be collectively formed as described later. Note that the p-type impurity concentration of the low-concentration region 27 may be lower than the p-type impurity concentration of the low-concentration region 26. Thus, the avalanche capability of the semiconductor device 1A can be further improved.

Further, in the present embodiment, the low-concentration region 26 is disposed at the center of the inner region IA on the lower surface 2a of the semiconductor layer 2. Thus, the switching loss at the center of the inner region IA where the current density is high can be reduced, and the switching of the semiconductor device 1A can be efficiently speeded up.

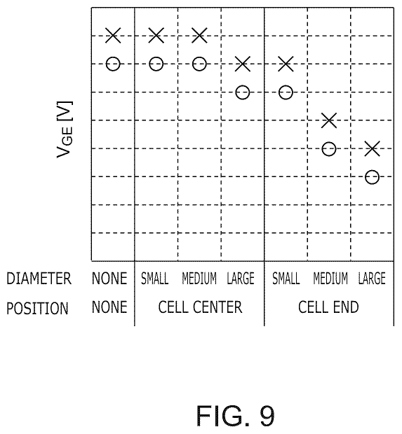

Further, the low-concentration region 26 is separated from the boundary B1 between the outer peripheral region OA and the inner region IA by ¼ or more of the width d of the inner region IA. Thus, the short circuit tolerance of the semiconductor device 1A can be improved. Hereinafter, this effect will be described in detail with reference to FIG. 9. FIG. 9 is a graph illustrating evaluation results of a short circuit tolerance in the semiconductor devices according to the first embodiment, the second embodiment, and a comparative example.

The horizontal axis in FIG. 9 represents the diameter and position of the low-concentration region 26 in each semiconductor device used for evaluating the short circuit tolerance. “None” indicates a case where the low-concentration region 26 is not provided. “Small”, “medium”, and “large” represent a case where the diameter of the low-concentration region 26 is 1/300, 1/100, and 1/60 of the width of the semiconductor layer 2, respectively. “Cell center” indicates a case where the low-concentration region 26 is located in a region (cell center) inside the boundary B2 in FIG. 8, that is, a case where the low-concentration region 26 is separated from the boundary B1 between the outer peripheral region OA and the inner region IA by ¼ or more of the width d of the inner region IA. “Cell end” indicates a case where the low-concentration region 26 is located in the region (cell end) between the boundary B1 and the boundary B2, that is, a case where the low-concentration region 26 is not separated from the boundary B1 by ¼ or more of the width d of the inner region IA. The semiconductor device 1 according to the first embodiment corresponds to the case of “none” in FIG. 9. Further, both the semiconductor device 1A according to the second embodiment and the semiconductor device 1B according to a first modification of the second embodiment correspond to the case of “cell center” and “large” in FIG. 9. The vertical axis in FIG. 9 represents the gate-emitter voltage applied to each semiconductor device. A cross (×) in the graph represents a gate-emitter voltage when the semiconductor device is destroyed, and a circle (◯) represents a gate-emitter voltage when the semiconductor device is not destroyed.

As illustrated in FIG. 9, when the low-concentration region 26 is located at the “cell center”, the short circuit tolerance of the semiconductor device is higher than that of the “cell end” regardless of the size of the low-concentration region 26. More specifically, the short circuit tolerance is higher in the case of “cell center” and “small” than in the case of “cell end” and “small”, the short circuit tolerance is higher in the case of “cell center” and “medium” than in the case of “cell end” and “medium”, and the short circuit tolerance is higher in the case of “cell center” and “large” than in the case of “cell end” and “large”. Therefore, since the low-concentration region 26 is separated from the boundary B1 between the outer peripheral region OA and the inner region IA by ¼ or more of the width d of the inner region IA, the short circuit tolerance of the semiconductor device 1A can be improved.

Note that, as illustrated in FIG. 9, in the case of “cell center” and “large”, the short circuit tolerance of the semiconductor device seems to be lowered as compared with the case of “cell center” and “small” or “cell center” and “medium”. However, although not illustrated, in the case of “cell center” and “large”, the failure mode of the semiconductor device changes. More specifically, in the case of “cell center” and “small”, or “cell center” and “medium”, the failure mode of the semiconductor device is destruction during turn-off. On the other hand, in the case of “cell center” and “large”, the failure mode of the semiconductor device was bias temperature (BT) failure which is thermal destruction after being turned off. Therefore, when the low-concentration region 26 is located at the cell center, the width of the low-concentration region 26 is equal to or more than 1/60 of the width of the semiconductor layer 2, so that the short circuit tolerance of the semiconductor device 1A can be further improved.

### Method for Manufacturing Semiconductor Device 1A

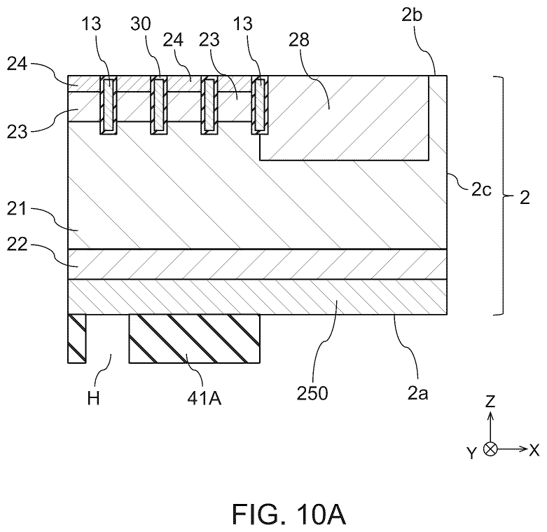

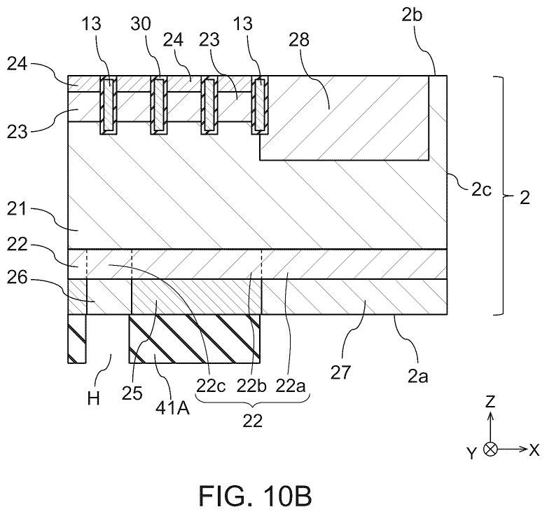

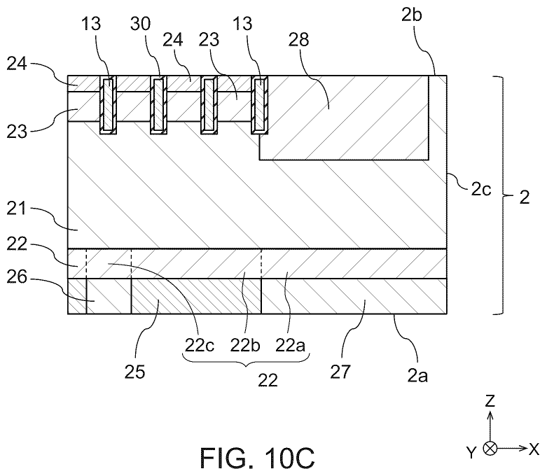

Next, an example of a method for manufacturing the semiconductor device 1A according to the present embodiment will be described with reference to FIGS. 10A to 10C, focusing on differences from the first embodiment. FIGS. 10A to 10C are cross-sectional views for describing an example of a manufacturing process of the semiconductor device 1A according to the second embodiment. Note that, in FIGS. 10A to 10C, a portion (fourth portion) of the p base region 23 in contact with the emitter electrode 12 is omitted.

After the step of forming the p region 250 described with reference to FIG. 4C, as illustrated in FIG. 10A, a resist 41A is formed on a part of the lower surface 2a of the semiconductor layer 2. More specifically, after a resist is formed on the lower surface 2a of the semiconductor layer 2, a portion of the resist located in the outer peripheral region OA and an opening H portion for forming the low-concentration region 26 later are removed by photolithography or the like. Thus, the resist 41A illustrated in FIG. 10A is formed.

Next, as illustrated in FIG. 10B, by ion-implanting (counter-doping) n-type impurities into the lower surface 2a of the semiconductor layer 2, the low-concentration regions 26 and 27 are formed. More specifically, in the lower surface 2a of the semiconductor layer 2, the low-concentration region 26 and the low-concentration region 27 are formed by ion-implanting n-type impurities into the outer peripheral region OA and the opening H not covered with the resist 41A. The n-type impurity used at this time is, for example, at least one of phosphorus (P) or arsenic (As). The p-type impurity concentration in each of the low-concentration region 26 and the low-concentration region 27 is the first concentration. On the other hand, the effective p-type impurity concentration of the low-concentration region 26 is the third concentration lower than the first concentration, and the effective p-type impurity concentration of the low-concentration region 27 is the second concentration lower than the first concentration. Through this step, the collector region 25 is formed in a portion of the p region 250 covered with the resist 41A. Note that the n-type impurity concentration of each of the low-concentration region 26 and the low-concentration region 27 is higher than the n-type impurity concentration of the collector region 25.

Note that, in the step of forming the low-concentration region 26 and the low-concentration region 27, some n-type impurities may diffuse into the buffer region 22. Accordingly, when the buffer region 22 is divided into the first portion 22a located in the outer peripheral region OA, the second portion 22b located in the inner region IA, and the fifth portion 22c located on the low-concentration region 26, the n-type impurity concentration in the first portion 22a may be higher than the n-type impurity concentration in each of the second portion 22b and the fifth portion 22c.

The subsequent steps are similar to those in the first embodiment.

As described above, in the method for manufacturing the semiconductor device 1A according to the second embodiment, after the p region 250 is formed, the n-type impurity is ion-implanted into a part of the lower surface 2a of the semiconductor layer 2 in the inner region IA to form the low-concentration region 26 in which the net p-type impurity concentration after the n-type impurity and the p-type impurity compensate each other is the third concentration lower than the first concentration, the low-concentration region 26 being surrounded by the collector region 25.

Thus, the semiconductor device 1A with high switching speed can be manufactured.

Further, according to the method for manufacturing the semiconductor device 1A according to the present embodiment, the low-concentration region 26 and the low-concentration region 27 can be collectively formed. In this case, the second concentration is equal to the third concentration.

Note that the low-concentration region 27 may be formed before or after the low-concentration region 26 is formed. Thus, the second concentration can be made different from the third concentration. For example, by making the second concentration lower than the third concentration, it is possible to manufacture the semiconductor device 1A in which the avalanche capability is further improved.

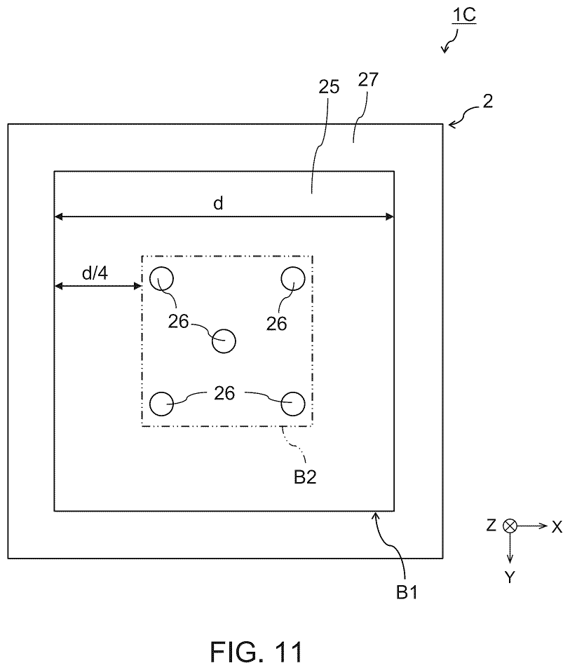

Further, a plurality of low-concentration regions 26 may be provided. Hereinafter, a semiconductor device 1C according to a second modification of the second embodiment will be described with reference to FIG. 11. FIG. 11 is a bottom view of a semiconductor device 1C according to the second modification of the second embodiment. Hereinafter, the present embodiment will be described focusing on differences from the second embodiment.

As illustrated in FIG. 11, the semiconductor device 1C according to the present modification includes a plurality of low-concentration regions 26. Specifically, in the example of FIG. 11, the semiconductor device 1C includes five low-concentration regions 26. Note that the number of low-concentration regions 26 may be four or less or six or more.

Each low-concentration region 26 is provided so as to be surrounded by the collector region 25 in the semiconductor layer 2 and is separated from each other. Each low-concentration region 26 is in contact with the collector electrode 11 and is electrically connected to the collector electrode 11.

The effective p-type impurity concentration of each low-concentration region 26 is lower than the effective p-type impurity concentration of the collector region 25. Note that the effective p-type impurity concentrations of the low-concentration regions 26 may be all equal, or the effective p-type impurity concentration of at least one low-concentration region 26 may be different from the effective p-type impurity concentrations of the other low-concentration regions 26.

In the example of FIG. 11, each low-concentration region 26 is located in a region (cell center) inside the boundary B2. Further, one low-concentration region 26 of the plurality of low-concentration regions 26 is located at the center of the lower surface 2a of the semiconductor layer 2.

Further, in the example of FIG. 11, the plurality of low-concentration regions 26 is symmetrically disposed on the lower surface 2a of the semiconductor layer 2. More specifically, the plurality of low-concentration regions 26 is arranged line-symmetrically with respect to a straight line that passes through the center of the lower surface 2a of the semiconductor layer 2 and is parallel to the X axis, and is arranged line-symmetrically with respect to a straight line that passes through the center and is parallel to the Y axis. Thus, the switching of the semiconductor device 1C can be efficiently speeded up. Note that the plurality of low-concentration regions 26 may be arranged line-symmetrically with respect to at least one straight line that passes through the center of the lower surface 2a of the semiconductor layer 2 and is parallel to an XY plane. Alternatively, the plurality of low-concentration regions 26 may be arranged point-symmetrically with respect to the center of the lower surface 2a of the semiconductor layer 2.

According to the present embodiment, since the plurality of low-concentration regions 26 is provided, the switching of the semiconductor device 1C can be made faster.

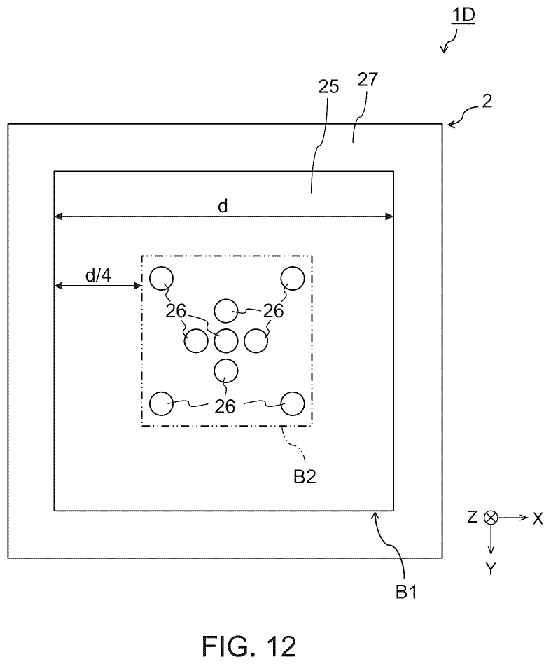

Note that the plurality of low-concentration regions 26 may be disposed so that the density increases toward the center of the lower surface 2a of the semiconductor layer 2. FIG. 12 is a bottom view of a semiconductor device 1D according to a third modification of the second embodiment.

In the example of FIG. 12, among the plurality of low-concentration regions 26, one located near the center of the lower surface 2a of the semiconductor layer 2 is closer to other low-concentration regions 26 than one located near the boundary B2. Accordingly Therefore, in the semiconductor device 1C, the density of the low-concentration region 26 is higher in the vicinity of the center of the lower surface 2a of the semiconductor layer 2 than in the vicinity of the boundary B2 of the lower surface 2a of the semiconductor layer 2. That is, in the example of FIG. 12, the plurality of low-concentration regions 26 is arranged so that the density increases as approaching the center of the lower surface 2a of the semiconductor layer 2. Thus, the switching of the semiconductor device 1D can be efficiently speeded up.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method for manufacturing a semiconductor device, the method comprising:
preparing a semiconductor layer including a first main surface and a second main surface and including a first semiconductor region of a first conductivity type, a second semiconductor region of a second conductivity type located on the first semiconductor region, a control electrode provided so as to face the second semiconductor region with an insulating region interposed therebetween, and a third semiconductor region of the first conductivity type located between the second main surface and the second semiconductor region;
ion-implanting an impurity of the second conductivity type into the first main surface of the semiconductor layer to form a fourth semiconductor region in which an impurity concentration of the second conductivity type is a first concentration; and
ion-implanting an impurity of the first conductivity type into the first main surface of the semiconductor layer in an outer peripheral region extending from a side portion of the semiconductor layer to an inside of the semiconductor layer to form a fifth semiconductor region in which a net impurity concentration of the second conductivity type after the impurity of the first conductivity type and the impurity of the second conductivity type compensate each other is a second concentration lower than the first concentration.

2. The method for manufacturing a semiconductor device according to claim 1, wherein an impurity concentration of the first conductivity type in the fifth semiconductor region is higher than an impurity concentration of the first conductivity type in the fourth semiconductor region.

3. The method for manufacturing a semiconductor device according to claim 2, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

4. The method for manufacturing a semiconductor device according to claim 1, wherein after the semiconductor layer is prepared and before the fourth semiconductor region is formed, an impurity of the first conductivity type is ion-implanted into the first main surface of the semiconductor layer to form a sixth semiconductor region in which an impurity concentration of the first conductivity type is higher than an impurity concentration of the first conductivity type of the first semiconductor region.

5. The method for manufacturing a semiconductor device according to claim 4, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

6. The method for manufacturing a semiconductor device according to claim 4, wherein
the sixth semiconductor region includes a first portion located in the outer peripheral region and a second portion located in an inner region inside the outer peripheral region, and
an impurity concentration of the first conductivity type in the first portion is higher than an impurity concentration of the first conductivity type in the second portion.

7. The method for manufacturing a semiconductor device according to claim 6, wherein after the fourth semiconductor region is formed, an impurity of the first conductivity type is ion-implanted into a part of the first main surface of the semiconductor layer in the inner region to form a seventh semiconductor region in which a net impurity concentration of the second conductivity type after the impurity of the first conductivity type and the impurity of the second conductivity type compensate each other is a third concentration lower than the first concentration, the seventh semiconductor region being surrounded by the fourth semiconductor region.

8. The method for manufacturing a semiconductor device according to claim 1, wherein
the forming the fifth semiconductor region includes:
forming a resist on the first main surface of the semiconductor layer, and then removing a portion of the resist located in the outer peripheral region;
ion-implanting an impurity of the first conductivity type into the first main surface of the semiconductor layer; and
removing a remaining portion of the resist.

9. The method for manufacturing a semiconductor device according to claim 8, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

10. The method for manufacturing a semiconductor device according to claim 1, wherein
the first conductivity type is an n-type, and
the impurity of the first conductivity type used for forming the fifth semiconductor region is at least one of phosphorus or arsenic.

11. The method for manufacturing a semiconductor device according to claim 10, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

12. The method for manufacturing a semiconductor device according to claim 1, wherein
the second conductivity type is a p type, and
the impurity of the second conductivity type used for forming the fourth semiconductor region is boron.

13. The method for manufacturing a semiconductor device according to claim 12, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

14. The method for manufacturing a semiconductor device according to claim 1, wherein after the fourth semiconductor region is formed, an impurity of the first conductivity type is ion-implanted into a part of the first main surface of the semiconductor layer in an inner region inside the outer peripheral region to form a seventh semiconductor region in which the net impurity concentration of the second conductivity type after the impurity of the first conductivity type and the impurity of the second conductivity type compensate each other is a third concentration lower than the first concentration, the seventh semiconductor region being surrounded by the fourth semiconductor region.

15. A semiconductor device comprising:
a semiconductor layer including a first main surface and a second main surface;
a first electrode provided on the first main surface;
a second electrode provided on the second main surface;
a first semiconductor region of a first conductivity type provided in the semiconductor layer;
a second semiconductor region of a second conductivity type provided in the semiconductor layer and located on the first semiconductor region;
a control electrode provided so as to face the second semiconductor region with an insulating region interposed therebetween;
a third semiconductor region of the first conductivity type provided in the semiconductor layer, located on the second semiconductor region, and electrically connected to the second electrode;
a fourth semiconductor region of the second conductivity type provided in the semiconductor layer, located between the first electrode and the first semiconductor region, and electrically connected to the first electrode, in which an impurity concentration of the second conductivity type is a first concentration; and
a fifth semiconductor region of the second conductivity type provided in an outer peripheral region extending from a side portion of the semiconductor layer to an inside of the semiconductor layer and electrically connected to the first electrode, the fifth semiconductor region including an impurity of the first conductivity type and an impurity of the second conductivity type, in which an impurity concentration of the second conductivity type is the first concentration, and a net impurity concentration of the second conductivity type after the impurity of the first conductivity type and the impurity of the second conductivity type compensate each other is a second concentration lower than the first concentration.

16. The semiconductor device according to claim 15, wherein an impurity concentration of the first conductivity type in the fifth semiconductor region is higher than an impurity concentration of the first conductivity type in the fourth semiconductor region.

17. The semiconductor device according to claim 16, further comprising a seventh semiconductor region of the second conductivity type provided in the semiconductor layer so as to be surrounded by the fourth semiconductor region and electrically connected to the first electrode, the seventh semiconductor region including an impurity of the first conductivity type and an impurity of the second conductivity type, in which an impurity concentration of the second conductivity type is the first concentration, and a net impurity concentration of the second conductivity type after the impurity of the first conductivity type and the impurity of the second conductivity type compensate each other is a third concentration lower than the first concentration.

18. The semiconductor device according to claim 15, further comprising:
a sixth semiconductor region of the first conductivity type provided in the semiconductor layer and located between the first semiconductor region and the fourth semiconductor region in which an impurity concentration of the first conductivity type is higher than an impurity concentration of the first conductivity type of the first semiconductor region, wherein
the sixth semiconductor region includes a first portion located in the outer peripheral region and a second portion located in an inner region inside the outer peripheral region, and
an impurity concentration of the first conductivity type in the first portion is higher than an impurity concentration of the first conductivity type in the second portion.

19. The semiconductor device according to claim 18, further comprising a seventh semiconductor region of the second conductivity type provided in the semiconductor layer so as to be surrounded by the fourth semiconductor region and electrically connected to the first electrode, the seventh semiconductor region including an impurity of the first conductivity type and an impurity of the second conductivity type, in which an impurity concentration of the second conductivity type is the first concentration, and a net impurity concentration of the second conductivity type after the impurity of the first conductivity type and the impurity of the second conductivity type compensate each other is a third concentration lower than the first concentration.

20. The semiconductor device according to claim 15, further comprising a seventh semiconductor region of the second conductivity type provided in the semiconductor layer so as to be surrounded by the fourth semiconductor region and electrically connected to the first electrode, the seventh semiconductor region including an impurity of the first conductivity type and an impurity of the second conductivity type, in which an impurity concentration of the second conductivity type is the first concentration, and a net impurity concentration of the second conductivity type after the impurity of the first conductivity type and the impurity of the second conductivity type compensate each other is a third concentration lower than the first concentration.
